(19) United States
(12) Patent Application Publication
(10) Pub. No.: US 2003/0037879 A1
(43) Pub. Date: Feb. 27, 2003

(54) Top gas feed lid for semiconductor processing chamber

(75) Inventors: Farahmand E. Askarinam, Sunnyvale, CA (US); Robert W. Wu, Pleasanton, CA (US); Jeremiah T. Pender, San Jose, CA (US); Gerardo A. Delgadino, Santa Clara, CA (US); Hoiman Hung, San Jose, CA (US); Ananda H. Kumar, Fremont, CA (US); Olga Regelman, Dale City, CA (US); Douglas A. Buchberger JR., Livermore, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/939,332

(22) Filed: Aug. 24, 2001

(51) Int. Cl. C23F 1/00; C23C 16/00; H01L 21/306

(52) U.S. Cl. 156/345.33; 118/715

(57) ABSTRACT

Apparatus for gas distribution in a semiconductor wafer processing chamber 200 having a roof 228. The roof 228 has a top surface 608 and a bottom surface 312. A recess 314 is disposed within the bottom surface 312 of the roof 228. A gas distribution plate 316 is disposed within the recess 314 and a material layer coating 320 is disposed upon the bottom surfaces 312/500 of the roof 228 and the gas distribution plate 316. The material layer coating 320 and the gas distribution plate 316 each have a plurality of apertures 322/404. The apertures 404 of the gas distribution plate 316 coincide with the apertures 322 in the material layer coating 320. The material layer coating 320 is formed from silicon carbide and most preferably is deposited by chemical vapor deposition (CVD). Both the roof 228 and gas distribution plate 316 are fabricated from silicon carbide.

### BACKGROUND OF THE DISCLOSURE

1. Field of the Invention

The present invention relates to a plasma process chamber for processing semiconductor substrates. More specifically, the invention relates to a lid for distributing process gases in the chamber.

2. Description of the Background Art

A plasma process chamber is used in semiconductor fabrication processes, for plasma enhanced chemical vapor deposition (CVD), reactive ion-etching (RIE), ion implantation and other similar processes. FIG. 1 shows a conventional process chamber 100 having one or more gas distributors 102 that provides process gas to the chamber 100. A power supply 104 powers coils 106 adjacent to the chamber 100 that inductively couples RF energy to the process gas to form a plasma. Process electrodes that are used to couple RF power to the plasma typically include a cathode (physically a support) 108 and an anode (physically a lid) 110. The cathode 108 is electrically insulated from the anode 110 by one or more insulator shields 120. A cathode power supply 114 applies an impedance matching RF bias power to the cathode 108 and the anode 110 is formed by electrically grounded sidewalls 112 and lid 110. The cathode 108 is capacitively coupled to the anode 110 via an electrostatic chuck 116 that rests on the support 108, an electrostatically retained substrate 118, and the plasma. The capacitively coupled electric field energizes and accelerates ions in a plasma toward the substrate 118.

Conventional chambers have problems that arise from the arrangement of the coils 106 adjacent to the chamber 100. Coils 106 that are parallel to the sidewalls 112 of the chamber 100 provide non-uniform fields across the substrate surface with strong inductive electric fields at the center of the substrate 118 and weak inductive fields at the peripheral edge of the substrate 118. One solution to this problem is to dispose the coils on top of the chamber having a dielectric material lid or ceiling. The coils inductively couple energy through flat dielectric ceilings (or lids) which allow RF inductive electric fields to permeate therethrough (not shown), but do not allow capacitive coupling of energy through the ceiling because it is made of non-conducting dielectric material. It is desirable for both the capacitive and inductive electric field components in the chamber to have highly directional vector field components that are substantially perpendicular to the surface of the substrate, and which extend uniformly across the entire substrate surface.

Dielectric ceiling material is typically alumina, aluminum oxide or some other dielectric material that is easily attacked and chemically reactive with fluorine based plasma. As such, the dielectric ceiling materials erode, introduce contaminant particles or are otherwise unsuitable for use with fluorine based plasmas. Additionally, process gas enters the chamber 100 through a distributor 102 as well as through the insulator shield 120 or other similar pedestal or process kit situated around the cathode 108. Since the gas distributor 102 is at one local or a few strategic locations, the dispersion pattern of the process gas cannot always reliably be uniform. Hence, non-uniform plasma is formed which effects overall substrate process conditions and the end product.

Thus, there is a need in the art for a plasma process chamber that provides a high density plasma with uniform energy distribution. More specifically, there is a need for a process chamber lid that can provide for more uniform distribution of process gases while also maintaining its electrical characteristics and structural integrity when being used in the presence of a plasma and particularly a fluorine based plasma.

### SUMMARY OF THE INVENTION

The disadvantages of the prior art are overcome by the present invention of an apparatus for gas distribution in a semiconductor wafer processing chamber having a roof fabricated from a silicon-based material, a recess disposed within said roof, a gas distribution plate disposed within said recess and a plurality of apertures disposed within the roof extending from the gas distribution plate. Further, the recess is disposed on a top surface of the roof and the roof has a plurality of grooves formed in the recess. A plurality of elongated apertures extend from the plurality of grooves into a bottom surface of the roof. Preferably, the roof and gas distribution plate are fabricated from silicon carbide.

In another embodiment of the invention, there is an apparatus for gas distribution in a semiconductor wafer processing chamber having a roof having a top surface and a bottom surface, a recess disposed within the bottom surface of said roof, a gas distribution plate disposed within said recess and a material layer coating disposed upon the bottom surface of the roof and the gas distribution plate. Further, the material layer coating and the gas distribution plate each have a plurality of apertures. The apertures of the gas distribution plate coincide with the apertures in the material layer coating. Preferably, the material layer coating is formed from silicon carbide and most preferably is deposited by chemical vapor deposition (CVD). Further still, both the roof and gas distribution plate are fabricated from silicon carbide.

### BRIEF DESCRIPTION OF THE DRAWINGS

The teachings of the present invention can be readily understood by considering the following detailed description in conjunction with the accompanying drawings, in which:

FIG. 1 shows a prior art plasma processing chamber;

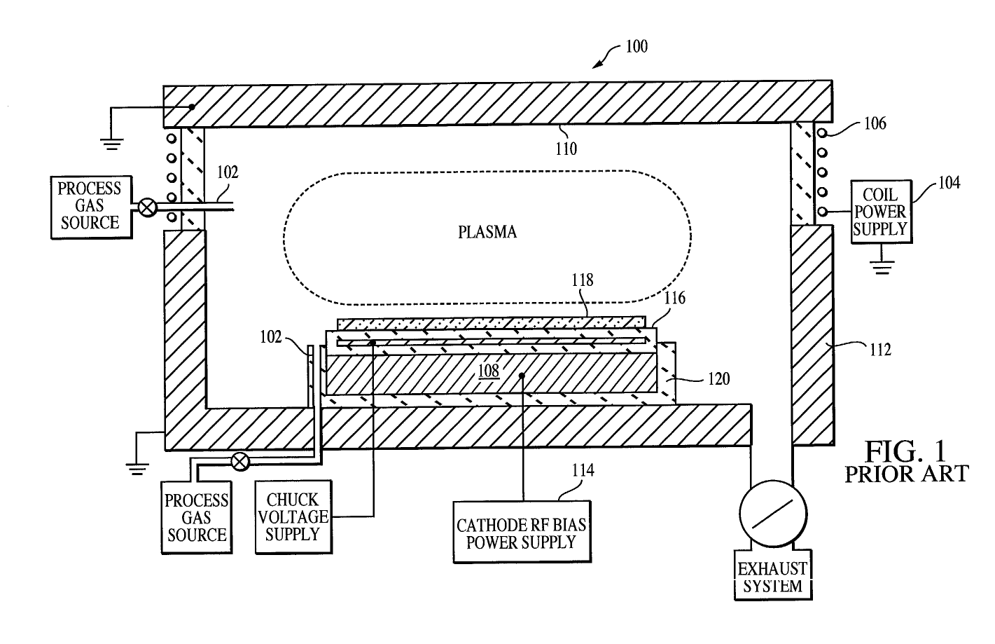

FIG. 2 shows a process chamber in accordance with the subject invention;

FIG. 3 shows a detailed view of a lid assembly in accordance with the subject invention;

FIG. 4 shows a top view of a gas distribution plate used in the lid assembly of FIG. 3;

FIG. 5 shows a bottom view of the gas distribution plate used in the lid assembly of FIG. 3;

FIG. 6 shows an alternate embodiment of the lid assembly in accordance with the subject invention; and

FIG. 7 shows a series of method steps for forming one embodiment of the subject invention.

To facilitate understanding, identical reference numerals have been used, where possible, to designate identical elements that are common to the figures.

### DETAILED DESCRIPTION

The present invention is directed to a plasma processing apparatus 200 used to process substrates 118 in a high density, highly directional, plasma formed in a process chamber 202. A high density plasma is a plasma having an ion energy density in excess of 10¹¹ ions/cm³ in contrast to conventional plasmas that have lower ion densities on the order of 10¹⁰ ions/cm³. By highly directional it is meant that the charged plasma ions and species are energized by electric field vector components 204 within a plasma zone 206 to accelerate in the direction substantially perpendicular to the substrate 118. The high density and highly directional plasma provides a large number of reactive plasma species that energetically impinge on the substrate 118 to efficiently chemically react with or transfer energy to the substrate. The highly directional plasma can be used to etch, implant, or deposit material on a substrate 118.

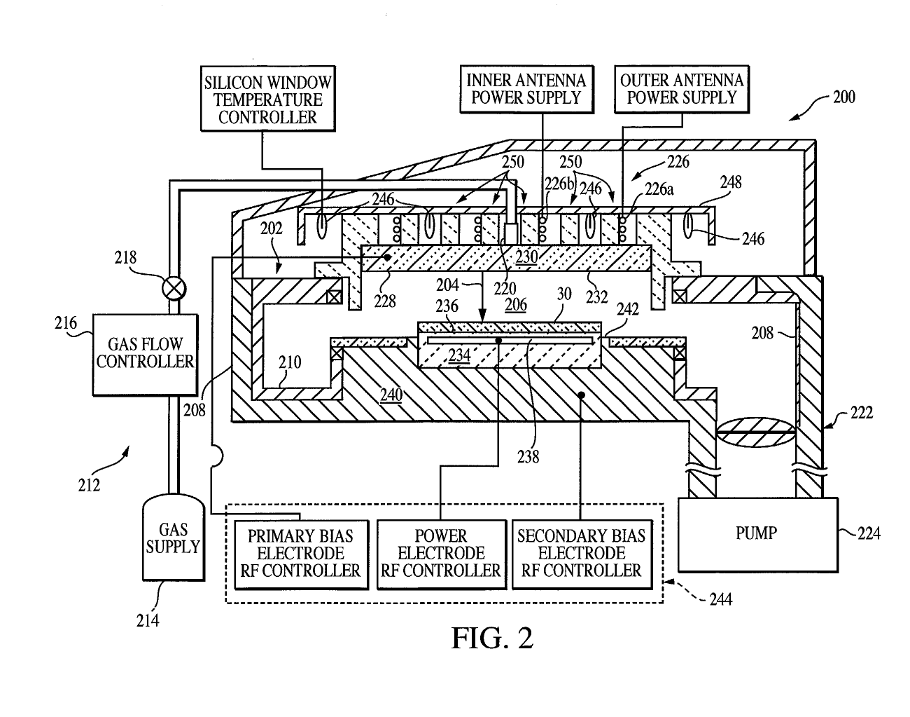

An exemplary plasma processing apparatus 200 of the present invention, is schematically illustrated in FIG. 2, and is provided only to illustrate an example of the present invention and should not be used to limit the scope of the invention. Detailed descriptions of this and similar exemplary chambers can be found in U.S. Pat. Nos. 6,095,083 and 6,095,084 both issued Aug. 1, 2000 and herein incorporated by reference. Generally, the apparatus 200 generally comprises an enclosed chamber 202 having sidewalls 208 and a bottom wall 210 fabricated from any one of a variety of materials including metals, ceramics, glasses, polymers and composite materials. Process gas is introduced into the chamber 202 through a gas distribution system 212 that distributes the gas in the chamber 202. The system 212 includes a process gas supply 214 and a gas flow control system 216 that operates gas flow meters 218 and a gas feed assembly 220. An exhaust system 222, comprising one or more exhaust pumps 224 (typically including a 1000 liter/sec roughing pump) is used to exhaust spent process gas and control the pressure of process gas in the chamber 202.

In the embodiment shown in FIG. 2, the chamber 202 comprises an antenna 226 adjacent to the chamber that generates an induction coupled field in the chamber to form a high density inductive plasma therein. The inductor antenna 226 preferably comprises multiple coils 226a and 226b positioned adjacent to a chamber ceiling 228 for inductively coupling RF power into the chamber 202. A primary bias electrode 230 comprises a first conducting surface 232 exposed to the plasma zone 206. A unitary monolithic dielectric member 234 positioned directly below the primary bias electrode 230 has a receiving surface 236 for receiving a substrate 118 thereon. A power electrode 238 is embedded in the dielectric member 234. The chamber 202 further comprises a secondary bias electrode 240 positioned directly below the dielectric member 234 and preferably having a second conducting surface 242 exposed to the plasma zone 206. An electrode voltage supply 244 is provided for maintaining the power electrode 238, and the primary and secondary bias electrodes 230, 240 at different electrical potentials relative to one another. Preferably, the power electrode 238 is used to carry both a DC chucking voltage and the RF bias voltage. The voltage supply 244 includes an AC voltage supply for providing a plasma generating RF voltage to the power electrode 238, and a DC voltage supply for providing a chucking voltage to the electrode 238. A separate DC voltage is applied to the electrode 238 to form an electrostatic charge that holds the substrate to the chuck. The RF power is coupled to a bridge circuit and a DC converter to provide DC chucking power to the electrode. The voltage supply 220 can also include a system controller for controlling the operation of the electrode by directing a DC current, and RF current, or both, to the electrode for chucking and dechucking the substrate 118 and for generating plasma in the process chamber 202.

Preferably, the ceiling 228 comprises silicon that is less likely to be a source of contamination for processing silicon substrates 118, in comparison with other materials. However, other well-known semiconductor materials can also be employed, such as silicon carbide, germanium, or Group III-V compound semiconductors such as gallium arsenide and indium phosphide, or Group II-III-V compound semiconductors such as mercury-cadmium-telluride. In a preferred embodiment, the ceiling 228 comprises a slab of semiconducting silicon having resistivity of less than about 500 .Ω.-cm (at room temperature), more preferably about 10 .Ω.-cm to about 300 .Ω.-cm, and most preferably about 20 .Ω.-cm to about 200 .Ω.-cm. If the ceiling 228 and a coating discussed in greater detail is silicon carbide, the resistivity is approximately 10⁴ Ω.-cm (at room temperature).

Active control of the temperature of the ceiling 228 is preferred to allow it to function both as an induction field window and as an electrode. The active temperature control of the window also provides a consistent and stable plasma, and good “cold start” conditions for the plasma. The temperature of the ceiling 228 is controlled using a plurality of radiant heaters such as tungsten halogen lamps 246 and a thermal transfer plate 248 made of aluminum or copper, with passages (not shown) for a heat transfer fluid to flow therethrough. A heat transfer fluid source (not shown) supplies heat transfer fluid to the passages to heat or cool the thermal transfer plate 248 as needed to maintain the chamber 202 at a constant temperature. The ceiling 228 is in thermal contact with the plate 248 via a plurality of highly thermally conductive rings 250.

The secondary bias electrode 240 serves as a bias or reference electrode positioned below the power electrode 238. The secondary bias electrode 240 has a diameter or width that is substantially equivalent or larger that the diameter or width of the power electrode 238. When the secondary bias electrode 240 is maintained at a slightly negative or positive potential relative to the power electrode 238, the secondary bias electrode 240 serves as a secondary biasing means to control the bias voltage field between the primary bias electrode 230 and the power electrode 238. The secondary bias electrode 240 also serves to reduce stray capacitances that would otherwise occur between the chamber walls 208 and the power electrode 238, by maintaining a difference in electrical potential between the power electrode and the secondary electrode that redirects such capacitive coupling effects, via a controllable electric field strength, toward the secondary bias electrode. The electric field strength between the two electrodes is controlled by adjusting the relative potential difference of the voltages applied to the two electrodes. The secondary bias electrode 240 comprises a conductor element of an electrically conductive material, such as aluminum, that is positioned directly below the dielectric member 234 that contains the power electrode 238.

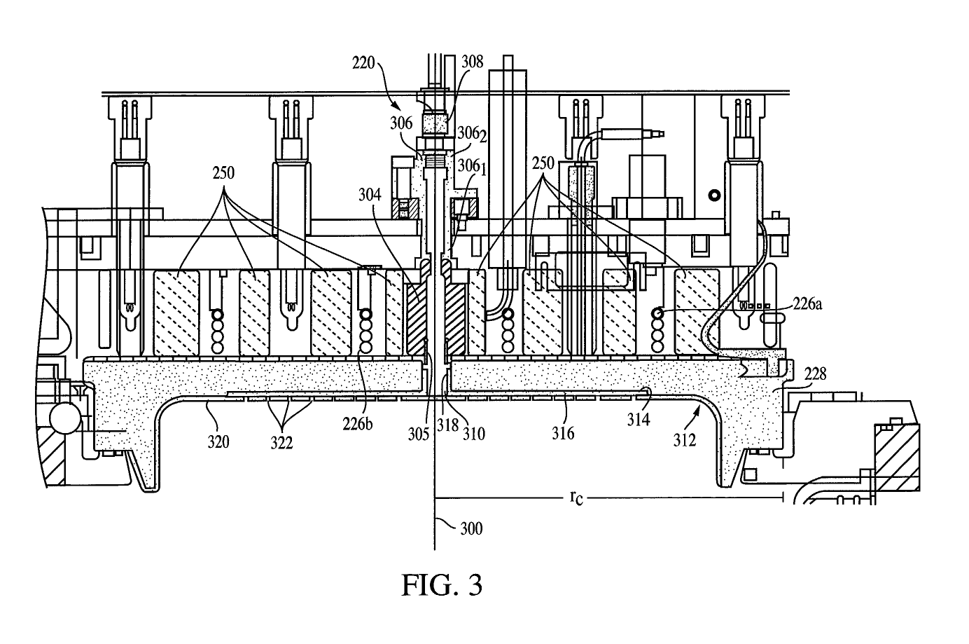

FIG. 3 illustrates a detailed view of one embodiment of the present antenna 226 and ceiling 228. The antenna 226 comprises coils having a circular symmetry with a central axis 300 and perpendicular to the plane of the substrate 118. Preferably, the antenna 226 comprises non-planar solenoid coils 226a and 226b which are stacked within each other. The process chamber 202 is a cylindrical chamber and the coil windings of the antenna 226 are vertically stacked as the two solenoids 226a, 226b to increase the product of current and antenna turns (d/dt)(N.I) near the ceiling 228 to provide a strong inductive flux linkage with close coupling to the plasma and therefore greater plasma ion density in the plasma zone 206 adjacent to the substrate 118. In a preferred arrangement, the solenoid coils comprise two four-turn solenoid coils, the inner coil 226b having a diameter of approximately 9 cms and the outer coil 226a having a diameter of about 25 cms. Each of the coils is liquid cooled to reduce heat transfer to the primary bias electrode 230. The coils 226a, 226b are powered by a three channel RF generator that provides more precise RF power control with higher reliability and eliminates active RF matching of impedances. The control system uses frequency tuning in mutually exclusive frequency ranges for each source coil and bias power source in combination with true delivered power control.

The ceiling 228 further comprises a gas feed channel 310. Preferably this gas feed channel 310 is disposed centrally with respect to the ceiling 228 and dielectric member 234 therebelow. Above the gas feed channel 310 and attached thereto is the gas feed assembly 220. The gas feed assembly 220 further comprises a gas feed tube 304, seals 305 and gas feed connector 306. The gas feed tube 304 is preferably quartz and may have one or more seals 305 at a point where it interfaces with the ceiling 228. Disposed above and attached to the gas feed tube 304 is the gas feed connector 306. The gas feed connector 306 is attached to the gas feed tube 304 on a first end 306₁ and is provided with a fitting at a second end 306₂ to receive a gas supply fitting 308.

A bottom surface 312 of the ceiling 228 contains a recess 314. The recess 314 extends radially outward from the gas feed channel 310 to a point approximately two thirds of the radius of the ceiling r_{c}. A distribution plate 316 is disposed within the recess 314. In one embodiment, and as shown in FIG. 3, the distribution plate 316 further comprises a flange 318 which is disposed within the gas feed channel 310. The distribution plate 316 has a thickness that is approximately equal to the depth of recess 314. In this way, the bottom surface 312 of the ceiling 228 is relatively smooth. A coating 320 is disposed over the bottom surface 312 of the ceiling 228 and over the distribution plate 316. The coating is further provided with a plurality of apertures 322 (only a few of which are shown in FIG. 3 for the sake of clarity). The apertures in conjunction with the distribution plate 316 provide for the flow of process gas. The thickness of the coating 320 is approximately 2-4 mm and the diameter of the apertures 322 are approximately 0.51 mm.

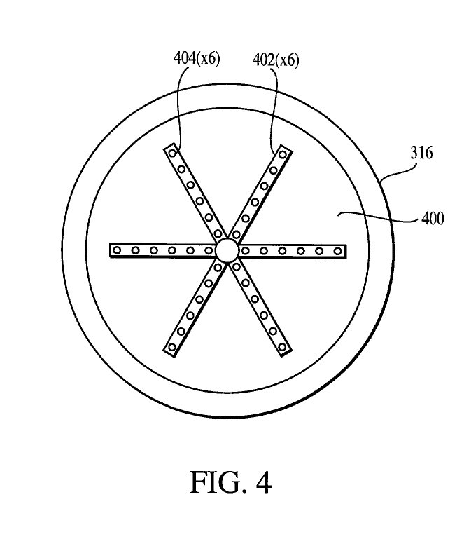

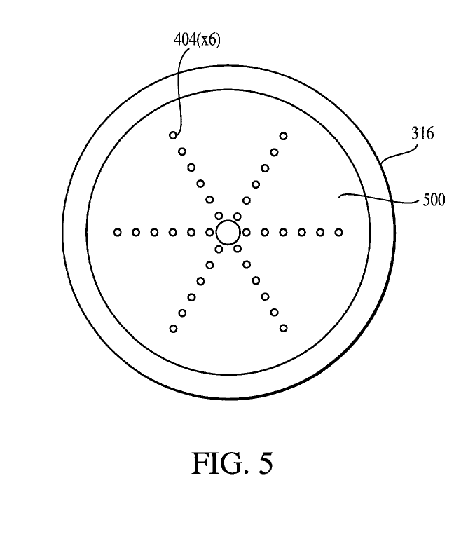

FIG. 4 depicts a top view of the distribution plate 316. The distribution plate 316 is provided with a plurality of grooves 402 on its top surface 400. Additionally, within each groove there is disposed a plurality of apertures 404. The plurality of apertures 404 extend through the distribution plate 316 from the top surface 400 to a bottom surface 500 as depicted in FIG. 5. The top surface 400 of the plate is inserted facing the recess 314. The bottom surface 500 forms a portion of the bottom surface 312 of the ceiling 228. The apertures 322 in the coating 320 correspond to the apertures 404 formed in the plate 316. As such, process gas is free to flow through the gas feed assembly 220 through the grooves 402 and apertures 404 in the plate 316, through the apertures 322 in the coating 320 and into the plasma zone 206. The grooves 402 are approximately 120 millimeters long, 5.0 millimeters wide, and 3.0 millimeters deep. The apertures 404 are approximately 0.51 millimeters in diameter. The apertures 322 are approximately 0.51 millimeters in diameter.

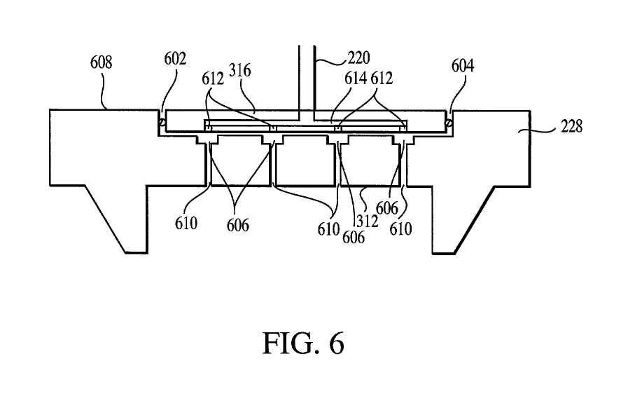

FIG. 6 shows a second embodiment of the invention wherein the ceiling 228 is depicted solely (that is without the chamber or additional hardware attached for sake of clarity). In this embodiment, a recess 602 is formed on a top surface 608 on the ceiling. Disposed within the recess 602 is the distribution plate 316. An airtight seal 604 circumscribes the distribution plate 316 so as to avoid contact between the interior of the chamber and the external atmosphere. The gas feed assembly 220 is attached to the distribution plate 316 in a manner similar to that of the first embodiment. At the bottom of the recess 602, a plurality of grooves 606 is formed. Although only four grooves are shown as formed, it will be known to one skilled in the art to form as many grooves as necessary to adequately distribute gas into the process chamber. At the bottom of each groove 606, an elongated aperture 610 is formed. The elongated aperture 610 extends from the bottom of the groove 606 to the bottom surface 312 of the ceiling. In this embodiment, a plurality of plate apertures 612 are provided in the plate 316, but do not extend totally therethrough. In one example as shown, the plurality of plate apertures 612 are joined to the gas feed assembly 220 via an internally disposed plenum 614. Other types of plate and aperture configurations will be known to those skilled in the art.

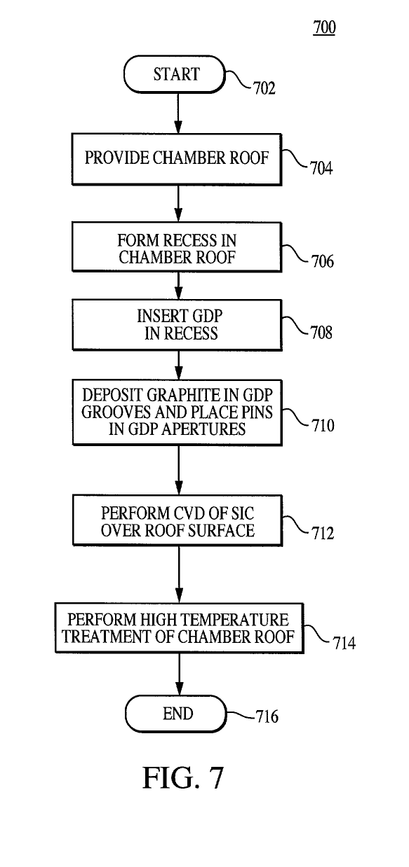

FIG. 7 depicts a series of method steps 700 for forming the ceiling in accordance with subject invention. Specifically, the method starts at step 702 and proceeds to step 704 wherein the ceiling is provided. Preferably, the ceiling is a solid, unitary body formed of the silicon carbide. The ceiling is further provided with a gas feed channel. In step 706, a recess is formed in the ceiling. The recess will define a space for disposing a gas distribution plate (GDP). At step 708, such a distribution plate is provided in the recess. Said gas distribution plate is preferably formed of silicon or silicon carbide. In step 710, graphite in powder form is deposited in grooves in the gas distribution plate and graphite pins are disposed in apertures in the gas distribution plate. The graphite powder prevents deposition material from entering the GDP grooves; the pins which extend perpendicularly from the grooves define aperture spaces to be formed in a subsequent coating. At step 712, a CVD operation of silicon carbide is performed thereby covering a ceiling surface and the GDP. The CVD operation is performed until the coating thickness is approximately 2-4 mm. After the CVD operation is performed, a high temperature treatment of the ceiling is performed at step 714. Specifically, the ceiling is baked in a high temperature apparatus to a temperature above approximately 900° C. for a time of 2-8 hours. The high temperature treatment oxidizes or otherwise burns off the graphite powder and pins thereby leaving apertures in the coating and reclaiming the grooves previously formed in the GDP. As such, it is possible for a gas to travel from the gas feed channel in the ceiling through the grooves of the GDP and through the apertures formed in the coating to enter a chamber there below.

Although various embodiments which incorporate the teachings of the present invention have been shown and described in detail herein, those skilled in the art can readily devise many other varied embodiments that still incorporate these teachings.

We claim:

1. Apparatus for gas distribution in a semiconductor wafer processing chamber comprising:
a roof fabricated from a silicon-based material;
a recess disposed within said roof;
a gas distribution plate disposed within said recess; and
a plurality of apertures disposed within the roof extending from the gas distribution plate.

2. The apparatus of claim 1 wherein the recess is disposed on a top surface of the roof.

3. The apparatus of claim 2 wherein a seal circumscribes gas distribution plate.

4. The apparatus of claim 2 wherein the roof further comprises a plurality of grooves formed in the recess.

5. The apparatus of claim 4 wherein the plurality of apertures disposed within the roof extend from each of said plurality of grooves into a bottom surface of the roof.

6. The apparatus of claim 1 wherein the roof is fabricated from silicon carbide.

7. The apparatus of claim 1 wherein the gas distribution plate is fabricated from silicon carbide.

8. The apparatus of claim 1 wherein the recess is formed on a bottom surface of the roof.

9. The apparatus of claim 8 wherein a gas feed channel extends from the top surface of the roof to the recess.

10. The apparatus of claim 8 wherein the bottom surface of the roof and the gas distribution plate are covered by a material layer.

11. The apparatus of claim 10 wherein the material layer is silicon carbide.

12. The apparatus of claim 11 wherein the material layer is deposited by chemical vapor deposition (CVD).

13. The apparatus of claim 10 wherein the material layer further comprises a plurality of apertures disposed therein.

14. The apparatus of claim 1 wherein the gas distribution plate further comprises a plurality of grooves.

15. The apparatus of claim 14 wherein the gas distribution plate further comprises a plurality of apertures disposed in each of said plurality of grooves.

16. The apparatus of claim 8 wherein the roof is fabricated from silicon carbide.

17. The apparatus of claim 8 wherein the gas distribution plate is fabricated from silicon carbide.

18. Apparatus for gas distribution in a semiconductor wafer processing chamber comprising:
a roof having a top surface and a bottom surface;
a recess disposed within the bottom surface of said roof;
a gas distribution plate disposed within said recess; and
a material layer coating disposed upon the bottom surface of the roof and the gas distribution plate.

19. The apparatus of claim 18 wherein the material layer coating further comprises a plurality of apertures.

20. The apparatus of claim 19 wherein the gas distribution plate further comprises a plurality of apertures.

21. The apparatus of claim 20 wherein the apertures of the gas distribution plate coincide with the apertures in the material layer coating.

22. The apparatus of claim 18 wherein the material layer coating is formed from silicon carbide.

23. The apparatus of claim 18 wherein the material layer is deposited by chemical vapor deposition (CVD).

24. The apparatus of claim 18 wherein the roof is fabricated from silicon carbide.

25. The apparatus of claim 18 wherein the gas distribution plate is fabricated from silicon carbide.
